(19) United States
(12) Patent Application Publication
(10) Pub. No.: US 2009/0098854 A1
(43) Pub. Date: Apr. 16, 2009

(54) Method of providing billing and payment service using settlement service function of mobile electronic wallet and system therefor

(75) Inventors: Shae Jin Park, Bucheon-city (KR); Myoung Man Hur, Seoul (KR); Jung Hun Kim, Seoul (KR)

Correspondence Address: AKERMAN SENTERFITT, 8100 BOONE BOULEVARD, SUITE 700, VIENNA, VA, 22182-2683, US

(73) Assignee: HarexInfotech Inc., Seoul (KR)

(21) Appl. No.: 11/907,339

(22) Filed: Oct. 11, 2007

(51) Int. Cl. H04M 11/00; H04Q 7/20; H05K 11/00

(52) U.S. Cl. 455/407; 455/344; 455/406; 455/466

(57) ABSTRACT

Provided is a method of providing a billing and payment service using a settlement service function of a mobile electronic wallet, and a system therefor, which enables companies to charge customers for rates through their mobile devices, respectively, and enables the customers to directly pay for the rates using a settlement service function of a mobile electronic wallet without exposing banking information to a rate receipt institution on a regularly monthly basis. A rate guidance message is sent to a customer using a short message service (SMS) that is a wireless communication network service of a mobile device. If the customer confirms the guidance message, the mobile device automatically gains access to the rate demand company by call back URL or TCP/IP communication. Then, after undergoing a simple authentication procedure for confirming whether or not the access person is a true person, a rate bill including payment particulars is displayed on a screen of the mobile device. If the customer confirms the rate bill and intends to pay for the rate bill, the customer directly settles the payment using a settlement service function (e.g. credit card or account transfer of an electronic wallet of the mobile device. Thus, without exposing customer's settlement information such as account number and card number, the rate can be paid according to the customer's payment intent, to thereby reduce pressure by banking information exposure, and reduce congestion due to visit of banks using an electronic wallet settlement service function of the mobile device. A payment priority ranking order can be determined within a customer's allowable capital extent, and payment tools such as transfer account and credit card are diversified, to thereby prevent a payment delay due to lack of deposit money and enhance a rate receipt efficiency of the rate demand company.

### BACKGROUND OF THE INVENTION

1. Field of the Invention

The present invention relates to a method of providing a billing and payment service using a settlement service function of a mobile electronic wallet, and a system therefor, and more particularly, to a method of providing a billing and payment service using a settlement service function of a mobile electronic wallet, and a system therefor, which enables companies to charge customers for rates through their mobile devices, respectively, and enables the customers to directly pay for the rates using a settlement service function of a mobile electronic wallet without exposing banking information to a rate receipt institution on a regularly monthly basis.

2. Description of the Related Art

Credit card transfer, automatic transfer using bank account numbers, and a giro receipt and payment mode using a bank giro sheet are being used as rate payment methods of paying regularly monthly rates such as communication fees, insurance fees, newspaper charges, and public imposts.

In the case of the credit card transfer mode using any one of credit cards, information such as a card number, a valid date, and a card issuance company which is necessary to approve credit card transaction is registered in a rate demand company. The rate demand company requests for transaction approval to the card issuance company via a VAN (Value Added Network) company depending on a price demand due date every month. Then, the card issuance company performs a purchasing procedure of a sales slip for only the approved customers and pays the rate demand company for the rate on the basis of the purchased sales slip.

In the case of the rate payment method using credit cards, banking information such as card information is revealed to the rate demand company. As a result, banking accident using customer's credit card information may occur by malicious rate demand companies. Further, the vicious third party may reproduce card information in order to use the customer's card information illegally.

In the case of the automatic transfer using any one of account numbers, a customer informs a rate demand company of his or her own account number, bank code, bank branch code, etc. Then, the rate demand company notifies a corresponding financial agency of automatic transfer. As a result, an amount of money of the rate is automatically transferred to the rate demand company's account from the customer's account whenever the rate payment due date comes at a given cycle.

In the case of the automatic transfer using any one of account numbers like the credit card transfer mode, account information such as a bank code, an account number, and bank branch code that is very important personal information of the customer may be revealed to the rate demand company. In addition, since capital is automatically executed from the set bank account at the initial engagement once independently of the customer's capital execution will. As a result, flexibility of capital use by customer's need is limited. That is, for example, assuming that there are two items “A” and “B” for public imposts, a customer may pay for only the item “A” but may not pay for the item “B” according to the customer's payment schedule. In this case, the customer may temporarily use the relevant money to be paid for the item “B” by other usage and may pay for the item “B” together with overdue interest at a later time, under the customer's profitable situation. However, since automatic transfer have been established for the item “B,” the capital is automatically executed from the set bank account at a payment due date independently of the customer's capital execution will. As a result, the customer cannot use capital on a well-timed basis in view of the customer's standpoint. Further, when customer's account information is outpoured on the vicious third party, there are no principal confirmation procedures including password input etc., and thus the vicious third party may illegally use the customer's account information to thereby obtain improper gains. As a result, there may be problem that dispute may arise among the customers, rate demand companies, and financial agencies.

In the case of the giro receipt and payment mode using the giro sheet, a desired rate demand company registers giro payment in the Korea Financial Telecommunications & Clearing Institute and sends out giro sheets to corresponding customers. Then, the customer has the giro sheet and pays public imposts through the giro receipt financial agency.

The giro receipt and payment mode has advantages that do not reveal customer's banking information but disadvantages that the customer should visit the giro receipt financial agency directly to thus cause burdensomeness. If a customer loses a giro sheet, he or she should request relevant rate demand company to resend a new giro sheet. However, when re-issuance of the new giro sheet is not permitted, the customer may delay payment of public imposts reluctantly and thus may suffer from unnecessary financial burden.

### SUMMARY OF THE INVENTION

To solve the above problems of the conventional art, it is an object of the present invention to provide a method of providing a billing and payment service using a settlement service function of a mobile electronic wallet, and a system therefor, which enables companies to charge customers for rates through their mobile devices, respectively, and enables the customers to directly pay for the rates on a non-stop basis using a settlement service function of a mobile electronic wallet mounted on a mobile device without exposing banking information to a rate receipt institution on a regularly monthly basis, to thereby enable the customer to determine a payment schedule according to a payment priority order within the customer's budget extent.

It is another object of the present invention to provide a method of providing a billing and payment service using a settlement service function of a mobile electronic wallet, and a system therefor, which enables a customer to execute payment anytime anywhere using a communication function of a mobile device, to thereby solve inconveniences due to using banks, and solve popular discontent by repetition demand and excess demand by service cancellation in the case of automatic transfer customers.

To accomplish the above object of the present invention, there is provided a method of providing a billing and payment service using a mobile device having an electronic wallet function, the billing and payment service providing method comprising the steps of:

(a) registering franchises of a rate demand company in a mobile communication center in order to use a mobile automatic account transfer or mobile credit card transfer service as a rate receipt method of the rate demand company;

(b) receiving a mobile automatic account transfer or mobile credit card transfer which is requested from a customer as the rate receipt method of the rate demand company, and then registering a mobile device number, a mobile electronic wallet identification (MCID) for mobile settlement and mobile communication discrimination information in an electronic server of the rate demand company;

(c) requesting the mobile communication center to send a rate payment particulars information to a customer whose rate receipt mode has been registered as the mobile settlement in the electronic server of the rate demand company to thus make the mobile communication center transmit a rate demand guidance message to the mobile device of the customer;

(d) connecting as a network between the mobile device of the customer and the rate demand company after having confirmed the rate demand guidance message, and thus making the rate demand company transmit a rate demand itemized statement to the mobile device and determining whether or not settlement is executed; and

(e) at the time of the mobile settlement, enabling the customer to directly process the rate payment by the mobile settlement using a settlement function of the mobile electronic wallet mounted in the mobile device, and determining a payment ranking order for a number of rate demand rate demand itemized statements, to then execute payment settlement, and then at the time of settlement completion, entering completion of payment in a ledger of the rate demand company.

There is also provided a system for providing a billing and payment service using a settlement function of a mobile electronic wallet, the billing and payment service providing system comprising:

a mobile device having an electronic wallet storing account information, banking information of credit card information to thereby execute rate payment via mobile settlement;

a rate demand company system which comprises: sending a bill and invoice for payment rate such as communication fees, insurance fees, newspaper charges, and public imposts to a customer; sending a rate guidance message to a mobile device registered as a rate payment unit for mobile settlement by the customer; receiving a payment result; and executing the rate receipt process;

a financial agency system for banks of customers and rate demand companies, and credit card companies; and

a mobile communication center which comprises: sending a short message service (SMS) to a customer's mobile device according to a payment particulars information request of a rate demand company; requesting the financial agency system to settle the payment by automatic bank account transfer or credit card settlement according to a customer's mobile payment intent; and notifying the customer's mobile device and rate demand company of the mobile payment result.

### BRIEF DESCRIPTION OF THE DRAWINGS

The above and other objects and advantages of the present invention will become more apparent by describing the preferred embodiment thereof in more detail with reference to the accompanying drawings in which:

FIG. 1 is a schematic diagram showing a system for providing a billing and payment service using a settlement function of a mobile electronic wallet, according to the present invention;

FIG. 2 is a flowchart view to explain a method of providing a billing and payment service using a settlement function of a mobile electronic wallet, according to the present invention;

FIG. 3 illustrates states of the screen of a mobile device at the time of using mobile settlement;

FIG. 4 is a flowchart view illustrating a payment process flow using a mobile automatic (account) transfer of the FIG. 1 system; and

FIG. 5 is a flowchart view illustrating a payment process flow using a mobile credit card settlement of the FIG. 1 system.

### DETAILED DESCRIPTION OF THE INVENTION

A method of providing a billing and payment service using a settlement service function of a mobile electronic wallet, and a system therefor according to a preferred embodiment of the present invention will be described with reference to the accompanying drawings.

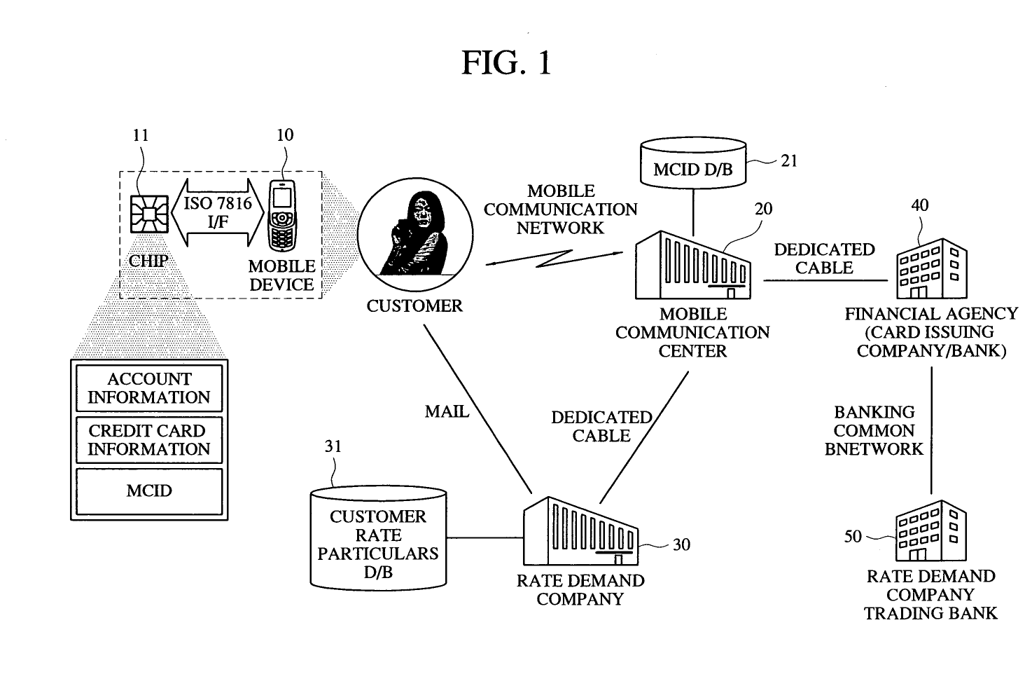

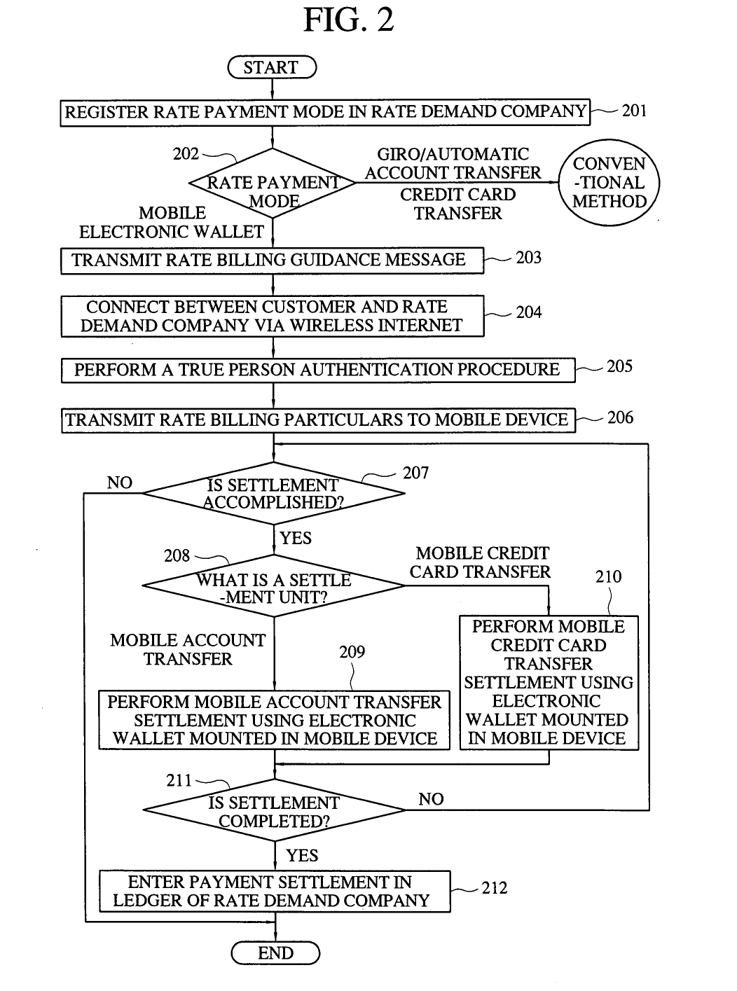

FIG. 1 is a schematic diagram showing a system for providing a billing and payment service using a settlement function of a mobile electronic wallet, according to the present invention. The system shown in FIG. 1 includes a mobile settlement integrated circuit (IC) chip 11 storing account information, banking card information of credit card information and a mobile device 10 such as a cellular phone, a mobile phone, a personal digital assistant (PDA), and a smart phone, for interface with the IC chip 11. The mobile communication center 20 plays a role of connecting between a customer and an account transfer bank in order to perform an account transfer and plays a role of a VAN (Value Added Network) company for a card transaction approval. A mobile chip identification (MCID) database (DB) 21 to register and manage mobile chip identification (ID) of the IC chip 11 mounted in the mobile device 10 is provided in the mobile communication center 20. The FIG. 1 system includes a rate demand company system 30 which comprises: sending a bill and invoice for payment rate to a customer; making the mobile communication center 20 send a rate guidance message to the mobile device 10 registered as a rate payment unit for mobile settlement by the customer; receiving a payment result; and managing the rate receipt process, and a financial agency system 40 such as credit card companies and banks receiving and processing a customer's account transfer or credit card settlement request via the mobile communication center 20, and notifying the customer of the processed result. The rate demand company 30 includes a customer rate particulars database (DB) 31 that manages the customer rate particulars by the database. The rate demand company trading bank 50 is linked by other financial agency 40 by a banking common network. A billing and payment service using a settlement service function of a mobile electronic wallet of the FIG. 1 system having the above-described configuration will be described in more detail with reference to FIGS. 2 to 5.

The mobile chip identification (MCID) is inherently added and stored in the IC chip 11 together with customer's account information for financial transaction and credit card information for commercial transaction payment. MCID is a value which is uniquely assigned by a customer. A card issuance company or a service administration agency assigns MCID to the IC chip card. Customers can refer to MCID through a menu of the mobile device 10.

The mobile device 10 includes an integrated circuit (IC) chip socket which operates with the IC chip 11. If the IC chip 11 is inserted into this socket, a customer has an electronic wallet settlement service function that can perform a mobile credit card settlement or a mobile account transfer using banking card information of the IC chip 11 through a menu such as a user interface of the mobile device 10.

FIG. 2 is a flowchart view to explain a method of providing a billing and payment service using a settlement function of a mobile electronic wallet, of the FIG. 1 system according to the present invention.

In FIG. 2, a customer registers a rate receipt mode in a rate demand company 30 (step 201). The customer registers the rate receipt mode through a mobile automatic transfer or mobile credit card transfer service application. Here, in the case of the information to be registered, customer's settlement information is not registered and only an inherent number of the mobile device 10 or MCID (mobile electronic wallet discrimination ID of mobile chip ID) and a mobile communication agency discrimination information, is registered. The rate demand company 30 distinguishes the customer's rate payment mode (step 202). If the customer's rate payment mode is one of existing giro/automatic account transfer/credit card transfer, etc., an existing rate demand and payment procedure is executed. If the customer's rate payment mode is a new mode using the mobile electronic wallet of step 202 in the discrimination result of step 202, the rate demand company 30 makes up a rate payment guidance message for the customer, and sends the same to the mobile communication agency 20 (step 203). The rate demand company 30 performs a payment particulars information request to the mobile communication center 20 of the registered mobile communication agency, and thus the mobile communication center 20 sends the far particulars notice to the customer's mobile device 10 via a short message service (SMS) according to the request.

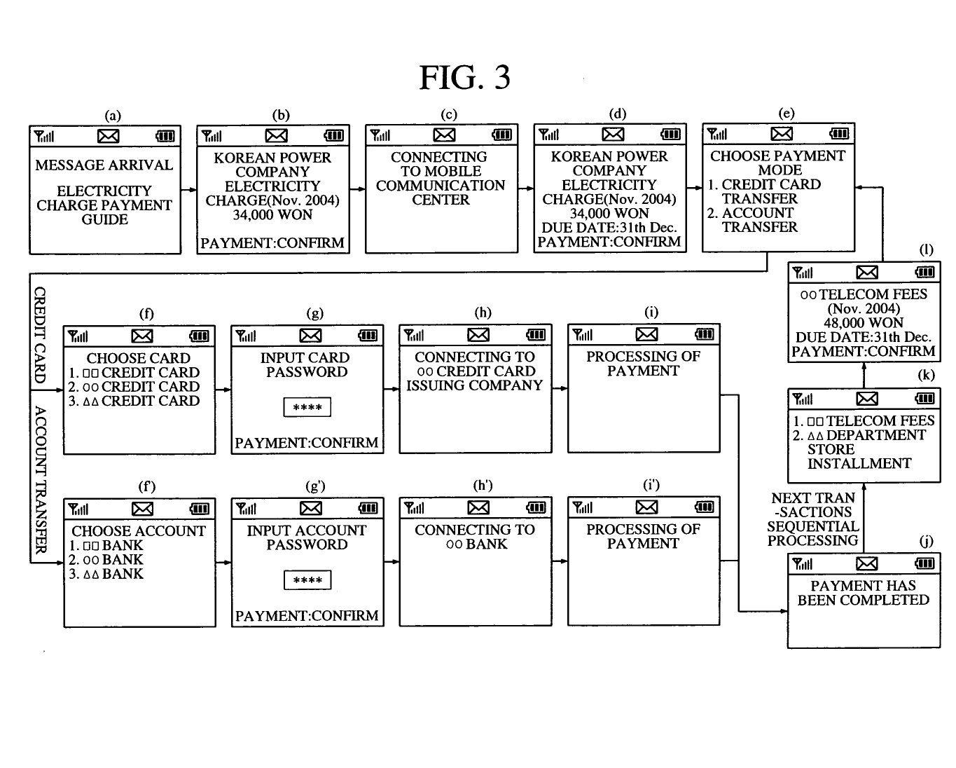

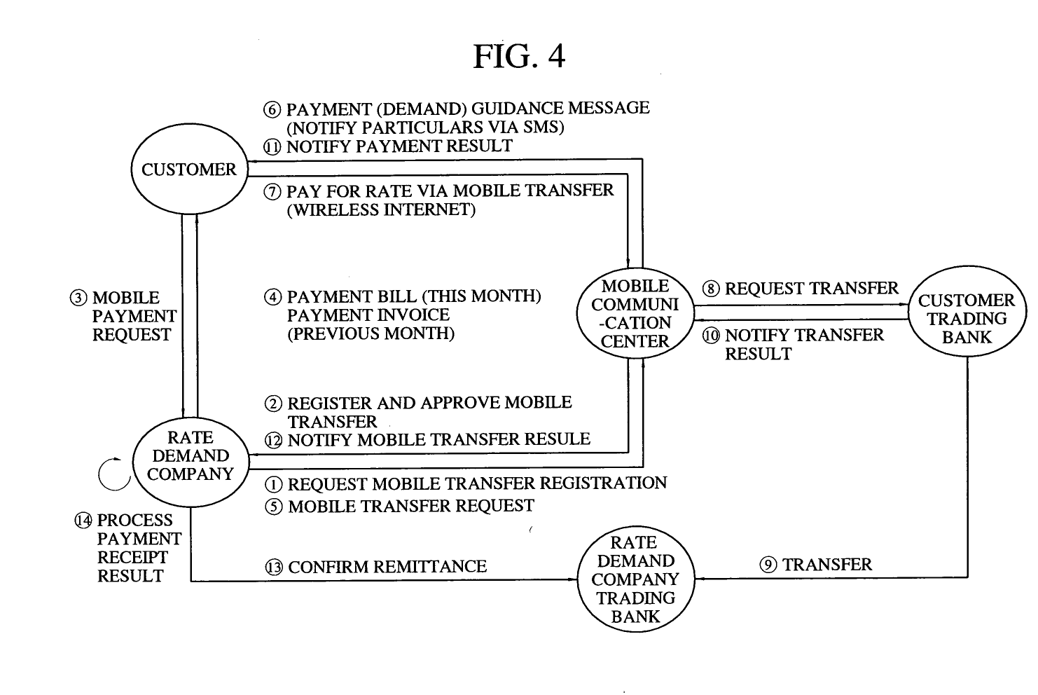

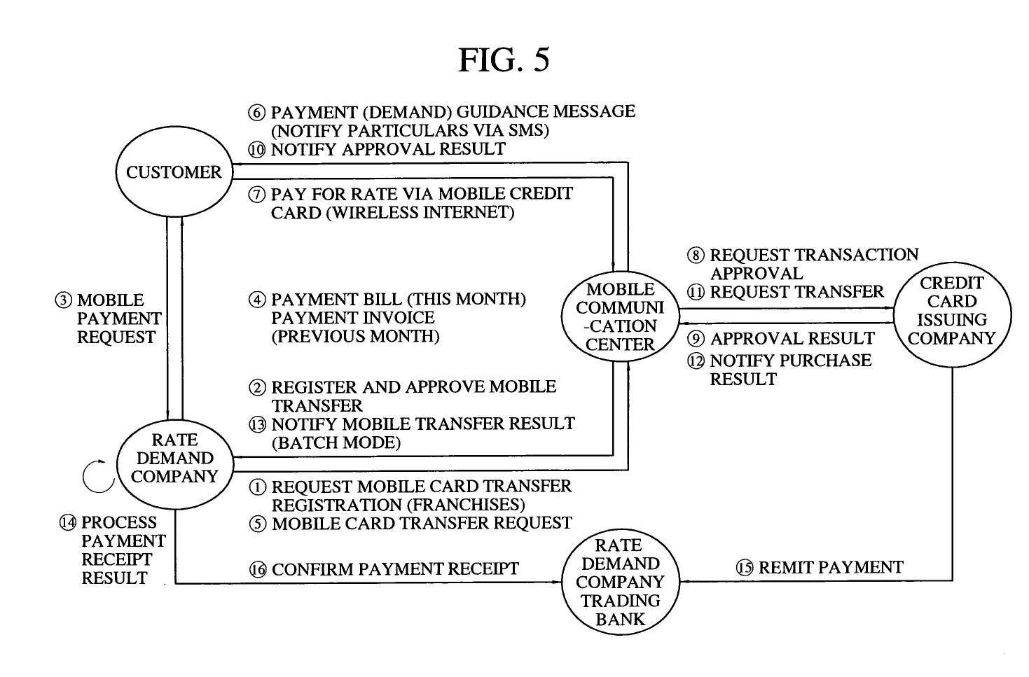

The customer sees a screen (a) of FIG. 3 that notifies “Message arrival,” and confirms a message content such as a title of a rate demand company and an amount of money to pay. At the time of SMS message confirmation of a screen (b) of FIG. 3, the customer is connected with the rate demand company 30 by the wireless internet on a one-to-one basis by Call Back URL or TCP/IP communication according to pressure of a call button (step 204). Here, a guidance message that the customer's mobile device 10 is being connected to the mobile communication center 20 is displayed on the screen of the customer's mobile device 10 as shown in a screen (c) of FIG. 3, and after the customer's mobile device 10 has been connected to the mobile communication center 20, a true person authentication procedure is performed (step 205). The rate demand company 30 requests the customer to input the residence number of the customer or the inherent number of the customer's mobile device 10 or the mobile chip identification (MCID) to thereby authenticate whether or not the customer is the true person. The customer inputs the true person authentication information through his or her mobile device 10, to thereby request the mobile communication center 20 or the rate demand company 30 to perform authentication. Accordingly, the mobile communication center 20 or the rate demand company 30 performs authentication. In the case that the customer inputs the mobile device number or MCID through the customer's mobile device 10 as the true person authentication information, the mobile communication center 20 confirms whether or not the customer is the true person through a prescriber information database. In the case that the customer inputs the residence number through the customer's mobile device 10 as the true person authentication information, the rate demand company 30 confirms whether or not the customer is the true person. The true person authentication procedure may be omitted. After having undergone the true person authentication, the rate demand company 30 sends rate demand particulars to the mobile device 10 (step 206). The mobile device 10 displays the rate demand particulars thereon as shown in a screen (d) of FIG. 3. The customer confirms the rate demand particulars on the screen (d) of FIG. 3, and determines whether or not he or she will settle the payment (step 207). If the customer does not intend to perform settlement of payment, the payment procedure through the mobile device is ended. If the customer intends to perform a settlement of payment, he or she chooses one of the payment settlement modes displayed on the screen (e) (step 208). That is, the customer selects his or her desired payment method on a payment method selection screen as shown in the screen (e) of FIG. 3. If the customer presses a numeric button “1” on the screen (e) of the mobile device 10 and selects “Credit card transfer,” a mobile credit card transfer settlement operation is performed using an electronic wallet that is mounted in the mobile device 10 (step 210). If the customer presses a numeric button “2” on the screen (e) of the mobile device 10 and selects “Account transfer,” a mobile account transfer settlement operation is performed using the electronic wallet that is mounted in the mobile device 10 (step 209). The detailed description relating to the mobile account transfer settlement operation and the mobile credit card transfer settlement operation will be described later with reference to FIGS. 4 and 5. Then, it is judged whether or not the settlement of payment is completed (step 211). If it has been judged that the settlement of payment has been completed for every rate demand item, the payment settlement result is entered into the ledger of the rate demand company 30 (step 212) and the procedure is ended. If the customer desires other rate demand items in sequence, he or she repeatedly performs the operations from steps 207 to 212. In the case that there are a number of rate demand bills or invoices to be settled, the customer may determine a payment priority ranking order of the rate demand bills or invoices, and may pay for the rate demand bills or invoices according to the payment priority ranking order within an allowable budget.

FIG. 4 is a flowchart view illustrating a payment process flow using a mobile automatic (account) transfer of the FIG. 1 system.

In FIG. 4, the rate demand company 30 requests for mobile transfer registration with respect to the mobile communication center 20 to add the mobile automatic transfer as the rate payment modes (\textcircled{1}), and receives mobile transfer registration approval from the mobile communication center 20 (\textcircled{2}). The rate demand company 30 for which the mobile automatic transfer payment mode is added receives a mobile payment application from the customer (\textcircled{3}), and sends the customer a rate demand and payment notice mail (\textcircled{4}). The rate demand company 30 also requests mobile transfer by customers in a batch process with respect to the mobile communication center 20 (\textcircled{5}). The mobile communication center 20 notifies the customer's mobile device 10 of a rate demand and payment guidance message through short message service (SMS) according to a mobile transfer request of the rate demand company 30 (\textcircled{6}). That is, the rate demand company 30 transmits the rate guidance message using the short message service to the customer via the mobile communication center 20 on the date designated by the customer who has selected the mobile automatic payment. Here, the communication center 20 transmits a Call Back URL for radio Internet connection or IP Address and Port Number for TCP/IP connection to the customer together with the rate payment guidance message (refer to the screens (a) and (b) of FIG. 3). The customer and the rate demand company 30 are connected with each other on a one-to-one basis by the wireless internet through call back URL or TCP/IP communication. Accordingly, the rate demand company 30 can transmit rate demand details to the customer's mobile device 10 (refer to the screens (c) and (d) of FIG. 3). The customer confirms the rate bill and directly performs a mobile transfer rate payment using a settlement service function of the electronic wallet of the IC chip 11 mounted in the mobile device 10 (\textcircled{7}). The mobile communication center 20 requests for transfer to the financial agency 40 that is the customer's trading bank according to the customer's mobile transfer rate payment intent (\textcircled{8}). That is, when the customer selects the mobile account transfer as the payment method, a display screen for account selection is displayed on the mobile device 10 as shown in a screen (f) of FIG. 3. Then, the customer chooses his or her bank account. The mobile communication center 20 is connected with the financial agency 40 of the corresponding bank according to the customer's account selection via a dedicated cable (refer to a screen (g) of FIG. 3). If the customer and the financial agency 40 are connected with each other on network, the financial agency 40 request for an account password input (refer to a screen (h) of FIG. 3). If a correct password has been input from the customer, the rate is paid through the account transfer (refer to a screen (i) of FIG. 3). That is, the financial agency 40 such as the customer's trading bank transfers the rate to the bank which the rate demand company 30 uses (\textcircled{9}), and notifies the transfer result to the customer's mobile device 10 via the mobile communication center 20 (\textcircled{10}) and (\textcircled{11}). Here, the mobile transfer result is notified to the rate demand company 30 on an online basis or in a batch processing mode (\textcircled{12}). The rate demand company 30 which has been notified the mobile transfer result confirms the payment through the trading bank 50 (\textcircled{13}) and processes the payment receipt result (\textcircled{14}).

FIG. 5 is a flowchart view illustrating a payment process flow using a mobile credit card settlement of the FIG. 1 system, in which the substantially same procedure is shown as shown in FIG. 4.

In FIG. 5, the rate demand company 30 requests for franchise registration for mobile card transfer registration to the mobile communication center 20 (\textcircled{1}), and receives the mobile credit card transfer registration approval from the mobile communication center 20 (\textcircled{2}). The rate demand company 30 receives a mobile credit card payment application from the customer (\textcircled{3}), and sends the customer a bill for this month and a payment notice of last month (\textcircled{4}). The rate demand company 30 requests the mobile communication center 20 to perform the mobile card transfers of customers in a batch process on scheduled dates, respectively (\textcircled{5}). The mobile communication center 20 which has received a mobile card transfer request transmits a payment (demand) guidance message using short message service to customers (\textcircled{6}) (refer to the screens (a) and (b) of FIG. 3). The customer confirms the SMS particulars on the screen of the mobile device 10 (refer to the screens (c) and (d) of FIG. 3). Then, the customer pays for the relevant rate via mobile credit card transfer using the settlement service function of the electronic wallet of the IC chip 11 containing the credit card information (\textcircled{7}). In the case that a number of pieces of card information are contained in the IC chip 11, a screen (f) of FIG. 3 is displayed on the mobile device 10, to make the customer select a card to use for payment. If the customer selects a card to use for payment, a password input is required (refer to a screen (g) of FIG. 3). If a correct card password has been input, the customer's mobile device 10 is connected with a server 40 in the credit card issuing company via the mobile communication center 20 (refer to a screen (h) of FIG. 3), and receives a transaction approval.

Here, the mobile communication center 20 plays a role of a value added network (VAN) company. That is, the mobile communication center 20 requests the credit card company 40 to perform a transaction approval request (\textcircled{8}), and notifies the customer's mobile device 10 of the approval result (\textcircled{9} and \textcircled{10}). The mobile communication center 20 requests the credit card company 40 to make purchase data on the basis of the transaction approval result and to request the purchase data (\textcircled{11}), and receives the purchased result from the credit card company 40 to then notify the rate demand company 30 of the purchased result on a batch process (\textcircled{12} and \textcircled{13}). The rate demand company 30 receives and treats respective rates by customers on the basis of the rate receipt result (\textcircled{14}). The credit card company 40 pays for the relevant rates to the bank account of the relevant rate company 30 through the rate demand company trading bank 50 (\textcircled{15}). The relevant rate demand company 30 connects to the relevant bank to confirm receipt of money (\textcircled{16}).

As described above, a method of providing a billing and payment service using a settlement service function of a mobile electronic wallet, and a system therefor, according to the present invention does not expose banking information to a rate receipt institution to thereby provide an effect of protecting personal information. In addition, the present invention enables an automatic transfer to be performed from a customer's account to a rate receipt institution account on a monthly basis by an one-time appointment, to thereby solve popular discontent by repetition demand and excess demand in the case of automatic transfer customers. In addition, the present invention enables a customer to execute payment anytime anywhere using a communication function of a mobile device, to thereby solve inconveniences due to using banks. Further, the present invention enables customers to select a settlement unit, to thereby enhance a rate receipt efficiency and prevent delay of payment. In addition, the present invention enables customers to determine a payment schedule according to a payment priority order within the customer's budget extent, in which case an interest of the delay can be calculated at the time of payment of the delayed rate, to thereby enable the customer to pay for the calculated delayed rate.

As described above, the present invention has been described with respect to particularly preferred embodiments. However, the present invention is not limited to the above embodiments, and it is possible for one who has an ordinary skill in the art to make various modifications and variations, without departing off the spirit of the present invention.

What is claimed is:

1. A method of providing a billing and payment service using a mobile device having an electronic wallet function, the billing and payment service providing method comprising the steps of:
(a) registering franchises of a rate demand company in a mobile communication center in order to use a mobile automatic account transfer or mobile credit card transfer service as a rate receipt method of the rate demand company;
(b) receiving a mobile automatic account transfer or mobile credit card transfer which is requested from a customer as the rate receipt method of the rate demand company, and then registering a mobile device number, a mobile electronic wallet identification (MCID) for mobile settlement and mobile communication discrimination information in an electronic server of the rate demand company;
(c) requesting the mobile communication center to send a rate payment particulars information to a customer whose rate receipt mode has been registered as the mobile settlement in the electronic server of the rate demand company to thus make the mobile communication center transmit a rate demand guidance message to the mobile device of the customer;
(d) connecting as a network between the mobile device of the customer and the rate demand company after having confirmed the rate demand guidance message, and thus making the rate demand company transmit a rate demand itemized statement to the mobile device and determining whether or not settlement is executed; and
(e) at the time of the mobile settlement, enabling the customer to directly process the rate payment by the mobile settlement using a settlement function of the mobile electronic wallet mounted in the mobile device, and determining a payment ranking order for a number of rate demand rate demand itemized statements, to then execute payment settlement, and then at the time of settlement completion, entering completion of payment in a ledger of the rate demand company.

2. The billing and payment service providing method of claim 1, wherein the step (c) comprises the step of transmitting a rate payment guidance message using a short message service to the mobile device of the customer via the mobile communication center on a customer appointment settlement day.

3. The billing and payment service providing method of claim 1, wherein the step (d) comprises the sub-steps of:
(d1) connecting by a wireless internet between the mobile device of the customer and the rate demand company using call back URL (User Resource Locator) or TCP/IP (Transfer Control Protocol/Internet Protocol) communication;
(d2) receiving at least one of a customer's residence number, the mobile device number, the mobile electronic wallet discrimination identification (MCID) and selectively accomplishing a true person authentication procedure at the rate demand company or mobile communication center; and
(d3) transmitting the rate demand itemized statement of the customer to the mobile device of the customer using the wireless internet.

4. The billing and payment service providing method of claim 1, wherein the step (e) comprises the steps of: connecting the mobile device of the customer with a relevant credit card company and executing payment if the customer chooses credit card transfer as the rate payment method at the time of the mobile settlement; and connecting the mobile device of the customer with a relevant bank if the customer chooses automatic account transfer as the rate payment method at the time of the mobile settlement, wherein a payment ranking order is determined for a number of rate demand rate demand itemized statements, and then payment settlement is sequentially executed according to the payment ranking order.

5. The billing and payment service providing method of claim 4, wherein the step (e) comprises the steps of: making the mobile communication center request the relevant bank designated by the customer to transfer the bank account at the time of payment of the rate via the mobile automatic bank account transfer designated by the customer, and then receive a transfer result; and notifying the mobile device of the customer of the rate payment result, to then notify the rate demand company of the transfer result on an on-line or batch mode basis.

6. The billing and payment service providing method of claim 4, wherein the step (e) comprises the sub-steps of: at the time of payment of the rate via the mobile credit card transfer designated by the customer,
(e1) selecting a card to use for rate payment among a number of pieces of card information;
(e2) inputting a password, and connecting a relevant credit card company through the mobile communication center if the input password is correct;
(e3) the mobile communication center requesting the credit card company for transaction approval and notifying the customer of the approval result;
(e4) the mobile communication center requesting the credit card company to make purchase data on the basis of the transaction approval result and to purchase the purchase data and notifying rate demand company of the purchase result on a batch mode basis; and
(e5) processing the rate by the customer on the basis of the rate receipt result at the rate demand company, and connecting to the relevant bank to confirm whether or not the payment settlement has been executed.

7. A system for providing a billing and payment service using a settlement function of a mobile electronic wallet, the billing and payment service providing system comprising:
a mobile device having an electronic wallet storing account information, banking information of credit card information to thereby execute rate payment via mobile settlement;
a rate demand company system which comprises: sending a bill and invoice for payment rate such as communication fees, insurance fees, newspaper charges, and public imposts to a customer; sending a rate guidance message to a mobile device registered as a rate payment unit for mobile settlement by the customer; receiving a payment result; and executing the rate receipt process;
a financial agency system for banks of customers and rate demand companies, and credit card companies; and
a mobile communication center which comprises: sending a short message service (SMS) to a customer's mobile device according to a payment particulars information request of a rate demand company; requesting the financial agency system to settle the payment by automatic bank account transfer or credit card settlement according to a customer's mobile payment intent; and notifying the customer's mobile device and rate demand company of the mobile payment result.

8. The billing and payment service providing system according to claim 7, wherein the electronic wallet of the mobile device is an integrated circuit (IC) chip storing customer's account information and credit card information, and mobile electronic wallet discrimination identification (MCID).

9. The billing and payment service providing system according to claim 7, wherein the rate demand company system comprises a customer rate customer particulars database (DB) to manage rate demand and payment particulars in database (DB), and wherein the rate demand company system registers franchises for mobile account transfer and credit card transfer in the mobile communication center, requests the mobile device of the customer to execute mobile account transfer and credit card transfer on a batch mode, and receives the transfer result to thereby process a rate payment result.

10. The billing and payment service providing system according to claim 7, wherein the financial agency system transfers a relevant rate from a customer's bank account to a rate demand company's trading bank account and notifies a transfer result to the mobile communication center according to the transfer request of the mobile communication center, and remits a relevant rate from the customer's bank account to the rate demand company's trading bank account according to a purchase request of a credit card transaction approval result of the mobile communication center and notifies the mobile communication center of the payment result.

11. The billing and payment service providing system according to claim 7, wherein the mobile communication center transmits call back URL (User Resource Locator) or internet protocol (IP) address for TCP/IP (Transfer Control Protocol/Internet Protocol) communication connection, and a port number to a customer's mobile device together with a rate payment guidance message, for wireless internet connection between the customer's mobile device and the rate demand company, and plays a role of connecting between the customer and an account transfer bank and a VAN (Value Added Network) function therebetween.
